(19) United States
(12) Patent Application Publication
(10) Pub. No.: US 2012/0104367 A1
(43) Pub. Date: May 3, 2012

(54) DISPLAY APPARATUS

(75) Inventors: Toshinori Hasegawa, Yokohama-shi (JP); Yojiro Matsuda, Kawasaki-shi (JP)

(73) Assignee: CANON KABUSHIKI KAISHA, Tokyo (JP)

(21) Appl. No.: 13/252,820

(22) Filed: Oct. 4, 2011

(30) Foreign Application Priority Data
Oct. 27, 2010 (JP) 2010-241206
Aug. 30, 2011 (JP) 2011-187167

(51) Int. Cl. H01L 27/32

(52) U.S. Cl. 257/40; 257/E27.119

(57) ABSTRACT

A display apparatus includes pixel units, each including a plurality of pixels having different emission colors. The pixel unit is provided with lenses so that the difference in deterioration property among the emission colors of the pixels.

### BACKGROUND OF THE INVENTION

1. Field of the Invention

The present invention relates to a display apparatus including organic EL elements.

2. Description of the Related Art

Display apparatuses including organic EL elements have enthusiastically studied and developed in recent years. An organic EL element includes an anode, organic compound layers including a luminescent layer, and a cathode. The anode and the cathode inject holes and electrons to the luminescent layer, respectively. The luminescent layer emits light using the recombination energy of the holes and electrons.

In order to display color images, for example, in a display apparatus including a plurality of organic EL elements emitting different colors, such as red, green and blue, the organic EL elements emits their respective colors to display white. However, the organic EL elements have different deterioration properties among colors (red, green and blue), and accordingly the white chromaticity varies among colors with time undesirably. This may be called white chromaticity deviation.

This will be described with reference to FIG. 7. FIG. 7 shows the relationship between the operation time t and the luminance (deterioration property) of red (R), green (G) and blue (B) organic EL elements when they were driven at a constant current. The relative luminance is represented relative to the luminance, defined as 1, at the beginning of current flow (t=0). In FIG. 7, when time is t=T, the green element has a relative luminance of about 0.55, and the red and blue elements have relative luminances of about 0.46 and about 0.31, respectively. The green element has a higher relative luminance than the other elements at t=T. Accordingly, even though a color displayed on a display apparatus is observed as white at t=0, the color is observed as a green-tinged white at t=T.

Japanese Patent Laid-Open No. 2001-290441 proposes increasing the lifetime of organic EL elements and reducing the white chromaticity deviation of the display apparatus by controlling the area of the light-emitting region emitting color light having a low luminous efficiency to reduce the current density flowing to the organic EL element.

However, display apparatuses have limitations in increasing or reducing the area of the light-emitting region, and the above-cited document cannot solve the issue of the difference in deterioration property among emission colors.

### SUMMARY OF THE INVENTION

The display apparatus of an embodiment of the invention includes a plurality of pixel units, each pixel units including a plurality of pixels having different emission colors. Each pixel includes an organic EL element having a deterioration property. The pixel unit is provided with at least one lens so as to reduce the difference in deterioration property among the emission colors of the pixels.

Further features of the present invention will become apparent from the following description of exemplary embodiments with reference to the attached drawings.

### BRIEF DESCRIPTION OF THE DRAWINGS

FIG. 1A is a schematic perspective view of a display apparatus according to a first embodiment of the present invention, and FIG. 1B is a fragmentary sectional view of the display apparatus.

FIG. 2 is a fragmentary sectional view of a known display apparatus.

FIG. 3 is a plot showing the relationship between the emission angle and the relative luminance.

FIGS. 4A to 4E are representations of a method for manufacturing the display apparatus according to the first embodiment.

FIG. 5 is a fragmentary sectional view of a display apparatus according to a second embodiment of the present invention.

FIGS. 6A to 6C are representations of a method for manufacturing the display apparatus according to the second embodiment.

FIG. 7 is a representation of a disadvantage of the known art.

### DESCRIPTION OF THE EMBODIMENTS

Exemplary embodiments of the invention will now be described with reference to the drawings. Parts of the display apparatus not shown in the drawings or not described in the following description are formed by techniques known in the art. Although the following description will illustrate some of the embodiments of the invention, the invention is not limited to the embodiments disclosed below.

The deterioration property of an organic EL element mentioned herein refers to a property of the organic EL element that changes in luminance (relative luminance) with operation time. To reduce the difference in deterioration property means that the variations in luminance (relative luminance) of organic EL elements driven for a certain time are brought closer to each other.

### First Embodiment

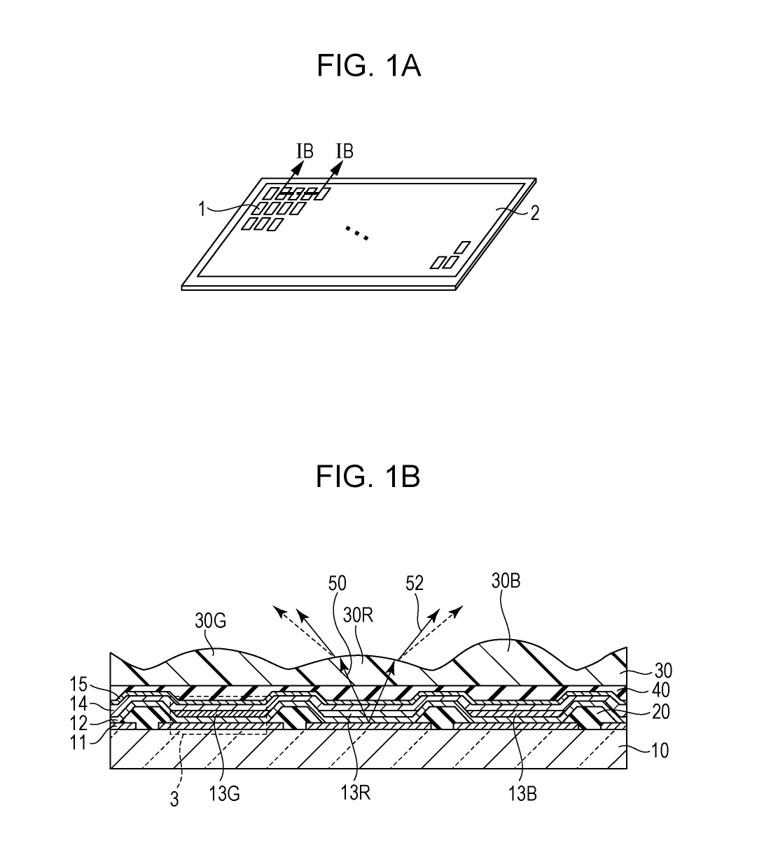

FIG. 1A is a schematic perspective view of a display apparatus according to a first embodiment of the present invention. The display apparatus of the present embodiment includes a plurality of pixels 1, each including an organic EL element. The plurality of pixels 1 are arranged in a matrix manner to define a display region 2. The pixel refers to a region corresponding to the light-emitting region of a light-emitting element. In the display apparatus of the present embodiment, the light-emitting element is an organic EL element, and each pixel 1 has an organic EL element that emits one color. The colors emitted from the organic EL elements include red, green and blue, and, in addition, may include yellow and cyan. In the display apparatus of the present embodiment, a set of pixels having different emission colors from each other (for example, three pixels emitting red light, green light and blue light) define a pixel unit, and a plurality of pixel units are arranged. The pixel unit is a minimum unit capable of emitting light having a desired color by mixing the colors of the pixels.

FIG. 1B is a fragmentary sectional view of the display apparatus taken along line IB-IB in FIG. 1A. Each pixel 1 includes an organic EL element 3 on a substrate 10. The organic EL element 3 includes a first electrode (anode) 11, a hole transport layer 12, any one of luminescent layers 13R, 13G and 13B, an electron transport layer 14, and a second electrode (cathode) 15. The luminescent layer 13R emits red light; the luminescent layer 13G emits green light; and the luminescent layer 13B emits blue light. The luminescent layers 13R, 13G and 13B are formed by pattering corresponding to the pixels 1 (organic EL elements 3) emitting red light, green light and blue light, respectively. The first electrode 11 of a pixel 1 (organic EL element 3) is separate from the first electrodes 11 of the adjacent pixels 1. The hole transport layer 12, the electron transport layer 14 and the second electrode 15 may be common to the adjacent pixels or may be provided for each pixel by patterning. In order that foreign matter causes short circuit between the first electrode 11 and the second electrode 15, an insulating layer 20 is provided between the pixels (more specifically, between the first electrodes 11).

In addition, the display apparatus of the present embodiment is provided with a lens member 30. The lens member 30 and the organic EL elements 3 are separated by a protective layer 40 that protects the organic EL elements 3 from moisture and oxygen. The lens member 30 has convex portions at the surface thereof, and convex lenses 30R, 30G and 30B are arranged corresponding to the pixels. The convex lenses 30R, 30G and 30B are adjusted so as to have different radiuses of curvature. Thus, the condensing characteristics of each lens can be varied among the pixels. In the present embodiment, the difference among the deterioration properties of the organic EL elements is reduced by adjusting the condensing characteristics of each lens according to the corresponding color. This will be further described in detail below. The condensing characteristics mentioned herein refer to the degree of the characteristics of lenses that reduces the emission angle of light at an interface to an angle less than the incident angle of the light. The condensing characteristics of a lens can be controlled by varying the area of the pixel occupied by the lens, the radius of curvature (or curvature) of the lens, the distance from the luminescent layer (organic EL element) to the lens, or the refractive index of the lens material.

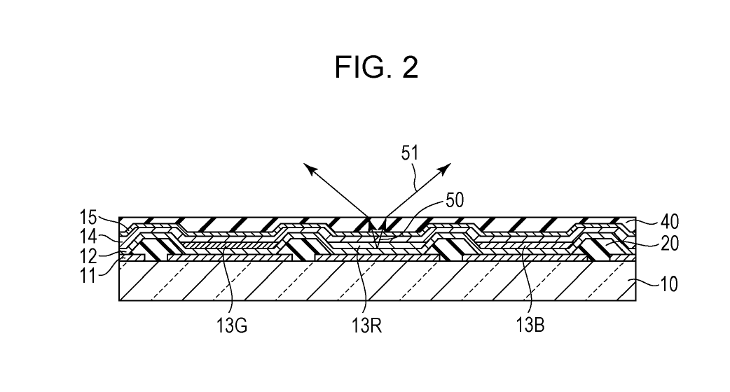

A consideration will now be made on a structure in which pixels are not provided with lenses with reference to FIG. 2. Light 50 emitted in oblique directions from an organic EL element goes out as more oblique light 51 in more oblique directions through the protective layer 40. On the other hand, in the case where a pixel is provided with a convex lens, such as lens 30R, as shown in FIG. 1B, light 50 emitted through the convex lens 30R goes out as light 52 in directions closer to the direction perpendicular to the surface of the substrate 10 (toward the front side of the display apparatus) in comparison with the case (dashed line) where the lens is not provided. Therefore, a structure provided with convex lenses can focus light more than a structure not provided with convex lenses. In other words, the luminance of a display apparatus observed from the front can be increased, and the light use efficiency of the display apparatus in the front direction can be increased.

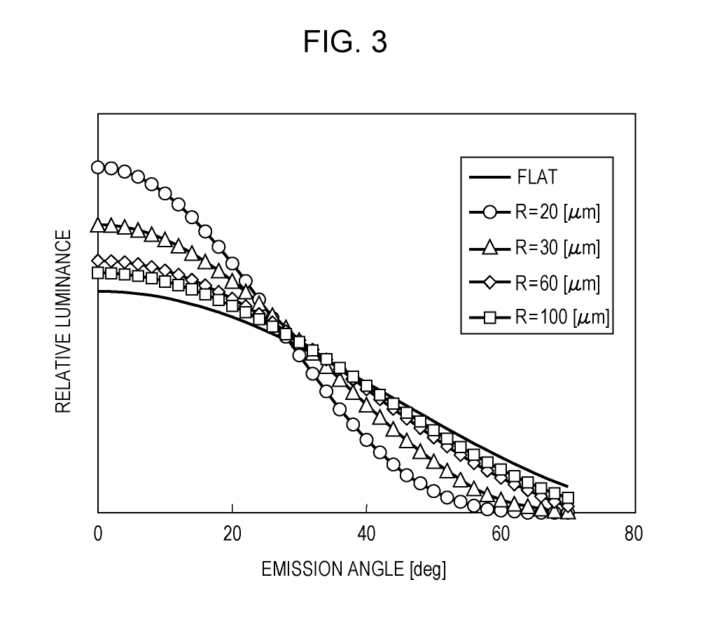

The curvature of a convex lens and the luminance in the front direction will now be described. FIG. 3 is a plot of the relationships between the emission angle and the relative luminance when the radiuses R of curvature of lenses are varied. In FIG. 3, “flat” represents the case where lenses were not used. Lenses of four types having radiuses R of curvature of 20 μm, 30 μm, 60 μm and 100 μm were used for measurement. Lenses of each type were provided for pixels having a width of 16.5 μm arranged at a pitch of 31.5 μm. The maximum width of the lenses was 31.5 μm. The second electrode 15 was made of a mixture of indium oxide and zinc oxide, and had a refractive index of 1.9 and a thickness of 0.05 μm. The protective layer 40 was made of silicon nitride, and had a refractive index of 1.83 and a thickness of 0.18 μm. The lens member 30 was made of an epoxy resin, and had a refractive index of 1.54 and a minimum thickness of 10 μm. The relative luminance refers to a value of luminance relative to the luminance (front luminance, defined as 1) measured at an emission angle of 0 degrees (in the front direction).

As shown in FIG. 3, when the lenses are formed so as to emit light at an emission angle of 30 degrees or less, particularly so as to emit light in the front direction, the relative luminance is higher in comparison with the case where lenses are not formed. Furthermore, when convex lenses are formed, the relative luminance increases as the radius of curvature of the convex lenses is reduced. This shows that a lens having a smaller radius of curvature has higher condensing characteristics than a convex lens having a larger radius of curvature. Hence, the condensing characteristics increase in this order: structure not provided with a lens, structure provided with a convex lens having a large radius of curvature, structure provided with a convex lens having a small radius of curvature. Accordingly, pixels provided with lenses having higher condensing characteristics exhibit higher relative luminances when viewed from the front of the display apparatus.

In general, however, the deterioration property of organic EL elements differs among their emission colors. This is probably because the luminous efficiency of the organic EL element depends on the material and thickness of the luminescent layer and other organic compound layers of the organic EL element. The current, more specifically, current density, applied to the organic EL elements for displaying white differs among the organic EL elements, depending on the difference in luminous efficiency among emission colors, and the luminance ratio of each color for displaying white. The magnitude of the current density affects the deterioration property of the organic EL element. More specifically, organic EL elements deteriorate sooner as the current density applied thereto is higher. Accordingly, in order to retard the deterioration of the organic EL element, the current density supplied to the organic EL element can be reduced. In order to promote the deterioration of the organic EL element, the current density supplied to the organic EL element can be increased.

Also, since display apparatuses are generally viewed from the front, a display apparatus exhibiting high front luminance is desirable. As described above, when the front luminous of a pixel provided with a lens having condensing characteristics is increased to the same level as a pixel not provided with a lens, the current density supplied to the organic EL element can be reduced to less than that supplied to the pixel not provided with a lens. This is because the luminance has a positive correlation with the current (current density). Therefore, deterioration can be suppressed by providing lenses having condensing characteristics.

Accordingly, in the display apparatus of the present embodiment, each pixel unit is provided with lenses whose condensing characteristics have been adjusted so as to reduce the difference in deterioration property among organic EL elements emitting different colors, and the lenses are disposed according to the colors emitted from the pixels. More specifically, a pixel having an organic EL element having a high deterioration rate (whose relative luminance is reduced at a high rate) is provided with a lens having high condensing characteristics, and a pixel having an organic EL element having a low deterioration rate (whose relative luminance is reduced at a low rate) is provided with a lens having low condensing characteristics. When the condensing characteristics are controlled by varying the radius of curvature of the convex lens, the pixel including an organic EL element having a high deterioration rate is provided with a lens having a small radius of curvature, and the pixel including an organic EL element having a low deterioration rate is provided with a lens having a large radius of curvature.

For example, a consideration will now be made on the case where the deterioration property differs among emission colors in a display apparatus whose pixels each have any one of an organic EL elements emitting red light (R element), an organic EL element emitting green light (G element) and an organic EL element emitting blue light (B element). More specifically, the case is considered where deterioration rate of the organic EL elements is increased in this order: the G element, the R element and the B element (deterioration rate of G element<deterioration rate of R element<deterioration rate of B element). In this instance, the condensing characteristics of the lenses can be increased in the order of the G element, the R element and the B element (condensing characteristics of G element<condensing characteristics of R element<condensing characteristics of B element). In this structure, the pixel having the B element provided with a lens having high condensing characteristics can exhibit an increased front luminance. Accordingly, the current density supplied to this pixel can be reduced to suppress the deterioration. Consequently, the deterioration rate of the B element is reduced. Even if it is driven for a long time, the decrease in relative luminance can be suppressed, and the deterioration property of the B element can be brought close to that of the G element. Similarly, the deterioration property of the pixel having the R element can be brought close to that of the G element. Since the deterioration properties of the B element and the R element thus become close to that of the G element, the chromaticity deviation of white, which is a mixed color of red, green and blue, can be prevented even after an operation for a desired period of time.

In a display apparatus that displays a desired white color by mixing a plurality of emission colors, it is preferable that the radius of curvature of the lens provided for each pixel be determined in view of the luminance ratio (color mixing ratio), luminous efficiency and luminance half-life of the colors required for displaying the white, as well as in view of the deterioration property of each color element. This will be further described below.

The CIExy chromaticity coordinates of red, green and blue in the front direction are (0.67, 0.33), (0.21, 0.71) and (0.14, 0.08), respectively. The luminous efficiency of red is 12 cd/A; that of green, 10 cd/A; and that of blue, 5 cd/A. The half-life of the red luminance is 80,000 hours; that of the green luminance is 90,000 hours; and that of the blue luminance is 10,000 hours. When white of chromaticity coordinates (0.31, 0.33) is displayed, the luminance ratio of red, green and blue is 3.2:5.8:1.0. Thus, the ratio of current required for red, green and blue is 1.3:2.9:1. The luminance half-life refers to the time taken until the luminance of an organic EL element decreases to a half the luminance at the beginning of the operation when the organic EL element is driven at a certain current.

Accordingly, when there is a negative correlation (inverse correlation) between the current required and the luminance half-life, the ratio of the luminance half-lives of red, green, and blue for displaying white is 6.0:3.1:1.0. If the ratio of the front luminances of red, green and blue is 1.0:3.1:6.0, the luminance balance of these colors at their luminance half-lives can be the same as that at the beginning of the operation, and thus the white chromaticity deviation can be reduced. Hence, the white chromaticity deviation can be reduced by providing lenses so that the front luminance ratio of red, green and blue can be 1:3.1:6.0. More specifically, the condensing characteristics of the lenses can be increased in the order of the R element, the G element and the B element (condensing characteristics of R element<condensing characteristics of G element<condensing characteristics of B element). The radiuses of curvature of the lenses may be determined according to an operation time based on a property of the display apparatus, such as the operation time taken from the beginning of the operation until the luminance decreases by several percent, instead of the half-life of luminance. In these cases, the difference in deterioration property among emission colors can be reduced relative to the case where the display apparatus does not have lenses. In the present embodiment, it has been assumed that the correlation between the luminance of emitted light and the operation time is negative and has a correlation coefficient of −1. However, the correlation coefficient can be calculated from the relationship between the luminance of light emitted from actual organic EL elements and their operation time.

The white chromaticity deviation is generally represented using CIE 1976 UCS chromaticity coordinates (u′, v′) (hereinafter referred to as u′ v′ chromaticity coordinates), which have the following relationships with the CIExy chromaticity coordinates (x, y):

$${u}^{′} = \frac{4 x}{- 2 x + 12 y + 3} , {v}^{′} = \frac{9 y}{- 2 x + 12 y + 3}$$

More specifically, the white CIExy chromaticity coordinates (0.31, 0.33) are represented as u′v′ chromaticity coordinates (0.20, 0.47).

If the chromaticity difference δu′v′ is 0.020 or less, it can be said that white chromaticity deviation is successfully controlled, wherein the chromaticity difference δu′v′ is expressed by the following relationship using the chromaticity (u′₀, v′₀) in u′v′ chromaticity coordinates at the beginning of the operation of the display apparatus and the chromaticity (u′ₜ, v′ₜ) after a predetermined time has elapsed:

δu′v′=\sqrt{(u′ₜ−u′₀)²+(v′ₜ−v′₀)²}

The condensing characteristics of the lenses are not necessarily varied among colors, and can be appropriately adjusted as needed. For example, even if the deterioration property is different among the R element, the G element and the B element, the lenses of the B and G elements may be adjusted so as to have the same condensing characteristics, and only the condensing characteristics of the lens of the R element may be different from the other lenses.

The condensing characteristics can be controlled by appropriately combining a structure provided with a convex lens and a structure not provided with a convex lens. For example, a pixel including an organic EL element having a high deterioration rate is provided with a convex lens, and another pixel including an organic EL element having a low deterioration rate may not be provided with a convex lens.

The substrate 10 is insulating and made of glass, plastic or the like, and has switching elements (not shown), such as TFTs or MIMs. The substrate 10 may have an insulating interlayer having contact holes through which the switching elements are electrically connected to the first electrodes 11. Furthermore, the substrate 10 may have a planarizing layer that flattens the unevenness of the switching elements.

The first electrode 11 may be a metal layer made of an elemental metal, such as Al, Cr or Ag, or an alloy of these metals. The first electrode 11 may further include a transparent oxide conductive layer, such as a compound layer containing indium oxide and tin oxide or a compound layer containing indium oxide and zinc oxide, on the metal layer. The thickness of the first electrode 11 can be in the range of 50 to 200 nm. A “transparent” substance means that it has a light transmittance of 40% or more in the visible region (in the wavelength range of 400 to 780 nm).

The hole transport layer 12 includes at least one organic compound layer that can inject or transport holes. The electron transport layer 14 includes at least one organic compound layer that can inject or transport electrons. In addition, the hole transport layer 12 may include an electron blocking layer, if necessary, to prevent electrons from migrating from the luminescent layer toward the anode. Also, the electron transport layer 14 may include a hole blocking layer. In addition, the hole transport layer 12 and the electron transport layer 14 may include an exciton blocking layer to prevent the diffusion of excitons produced from the luminescent layer.

The red luminescent layer 13R emitting red light, the green luminescent layer 13G emitting green light, and the blue luminescent layer 13B emitting blue light can be made known materials without particular limitation. For example, the luminescent layer may be composed of a single layer made of a material that can emit light and transport carriers, or may include a composite layer containing a luminescent material, such as a fluorescent material or a phosphorescent material, and a host material that can transport carriers.

The luminescent layers 13R, 13G and 13B, the hole transport layer 12 and the electron transport layer 14 can be formed of known materials by known methods, such as vapor deposition and transcription. The thicknesses of these layers can be optimized so as to enhance the luminous efficiency of the organic EL elements, and can be, for example, in the range of 5 to 100 nm.

The second electrode 15 may be a metal layer made of an elemental metal, such as Al, Cr or Ag, or an alloy of these metals. In particular, a metal thin film containing Ag can be used as the second electrode 15 because it is less absorbing and has a low specific resistance. The thickness of the second electrode 15 can be in the range of 5 to 30 nm. The second electrode 15 may have a multilayer structure including the above-described metal thin film and a transparent oxide conductive layer, such as a compound layer containing indium oxide and tin oxide or a compound layer containing indium oxide and zinc oxide, or may be composed of a transparent oxide conductive layer.

The protective layer 40 can be formed of a known material by a known method. For example, it may be formed of silicon nitride or silicon nitride oxide by CVD. The thickness of the protective layer 40 can be in the range of 0.5 to 10 μm from the viewpoint of ensuring its protection performance.

The lens member 30 may be made of a resin having a low water content such as a thermosetting resin, a thermoplastic resin, or a photo-curable resin. The thickness of the lens member 30 can be in the range of 10 to 100 μm. If the lens member 30 is formed of a thermosetting resin or a photo-curable resin, a spin coating or dispensing method can be applied. Alternatively, a thermoplastic resin film having a thickness of about 10 to 100 μm may be bonded on the protective layer 40 in vacuum. Epoxy resins and butyl resins can be used as the resin material of the lens member 30.

The lens member 30 may be made of an inorganic material, such as silicon nitride or silicon oxide. First, a silicon nitride or silicon oxide layer is formed to a thickness of about 20 μm by CVD, and then a structure in a shape of lenses is formed of a resin on the silicon nitride or silicon oxide layer. The resulting structure is subjected to dry etching to transfer the shape of lenses to the silicon nitride or silicon oxide layer.

The convex lenses 30R, 30G and 30B can be formed by any one of the following methods.

(1) A die having lens shapes is pressed on a resin layer to form lenses.
(2) A resin layer patterned by photolithography or the like is heated so as to be formed into lenses by reflowing.
(3) A photo-curable resin having a uniform thickness is exposed to light distributed in the in-plane direction, and the resin layer is developed to form lenses.
(4) The surface of a resin layer formed to a uniform thickness is worked into lenses by using an ion beam, an electron beam, or a laser beam.
(5) An appropriate amount of resin is dropped onto each pixel to form lenses in a self-aligned manner.
(6) A resin sheet on which lenses have been formed is prepared apart from the substrate having the organic EL elements, and is bonded to the substrate with alignment.

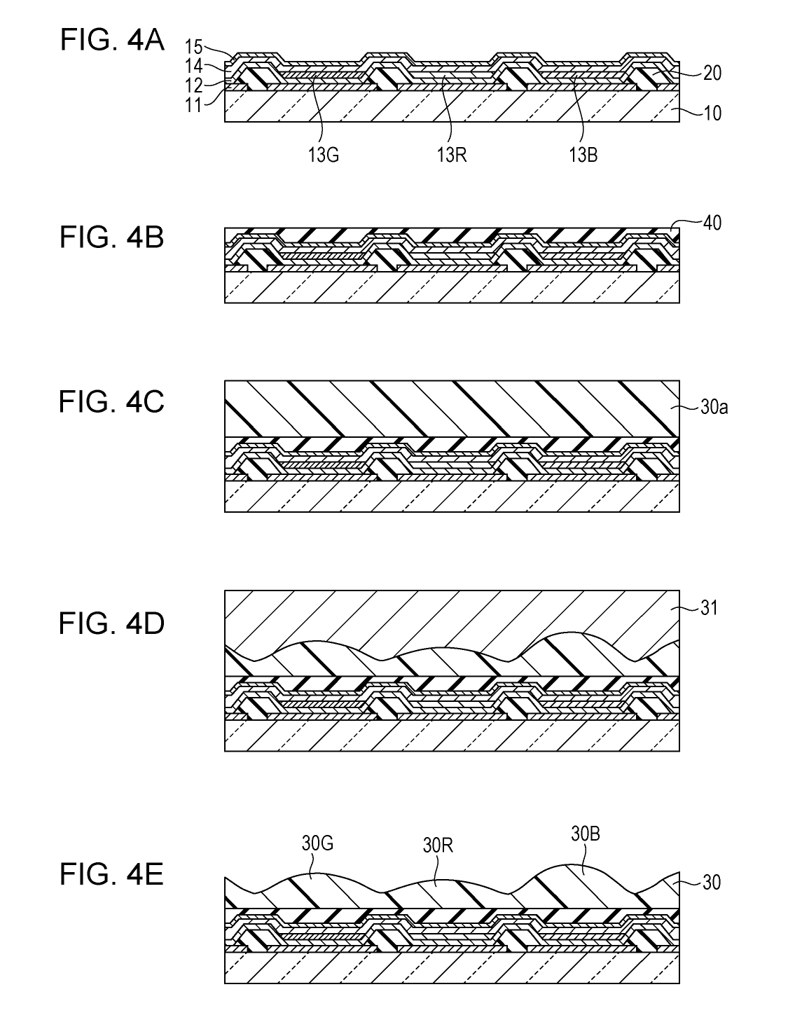

A process for manufacturing the display apparatus of the present embodiment using the above method (1) will now be described with reference to FIGS. 4A to 4E. The layers from the first electrode 11 to the second electrode 15 are formed on the substrate 10 by known methods, and thus description thereof is omitted.

First, as shown in FIG. 4A, top emission organic EL elements are formed on a substrate 10. Then, as shown in FIG. 4B, a protective layer 40 is formed over the entire display region so as to cover the organic EL elements. The protective layer 40 is intended to protect the organic EL elements from moisture and oxygen in the air, and from moisture in a resin material layer 30a that will be formed in a subsequent step. In addition, the protective layer 40 planarizes the surface of the substrate to help precise formation of the lenses.

Subsequently, as shown in FIG. 4C, the resin material layer 30a that will be formed into a lens member 30 is formed over the protective layer 40. Then, as shown in FIG. 4D, a die 31 is prepared for forming convex lenses 30R, 30G and 30B. The die 31 is pressed on the resin material layer 30a while preventing the entry of air. The surface of the die 31 coming into contact with the resin material layer 30a has recesses corresponding to the pixels. The radius of curvature of each recess is adjusted according to the condensing characteristics of the convex lens formed to the corresponding pixel.

The die 31 can be made of an ordinal metal. However, if the resin material layer 30a is formed of a photo-curable resin, the die 31 can be made of quarts because light must be transmitted through the die 31. From the viewpoint of increasing the releasability of the die 31 from the lens member 30, a fluorocarbon resin film or the like may be formed over the surface of the die 31.

If the resin material layer 30a is formed of a thermosetting resin, the resin material layer 30a is cured by being heated to 80° C. in a state where the bottoms of the recesses of the die 31 are substantially aligned with the centers of the corresponding pixels. Since organic compounds forming organic EL elements are generally resistant to temperatures up to about 100° C., the curing temperature of the resin material layer 30a can be about 80° C., lower than 100° C.

Then, as shown in FIG. 4E, the die 31 is removed from the cured lens member 30. Thus, the convex lenses 30R, 30G and 30B are formed corresponding to the pixels at the surface of the lens member 30.

If the convex lenses 30R, 30G and 30B are formed of a resin, a second protective layer (not shown) may be formed of an inorganic material over the lenses to protect the lenses from damage. The second protective layer 40 can be formed of the same material by the same method as the foregoing protective layer 40.

### Second Embodiment

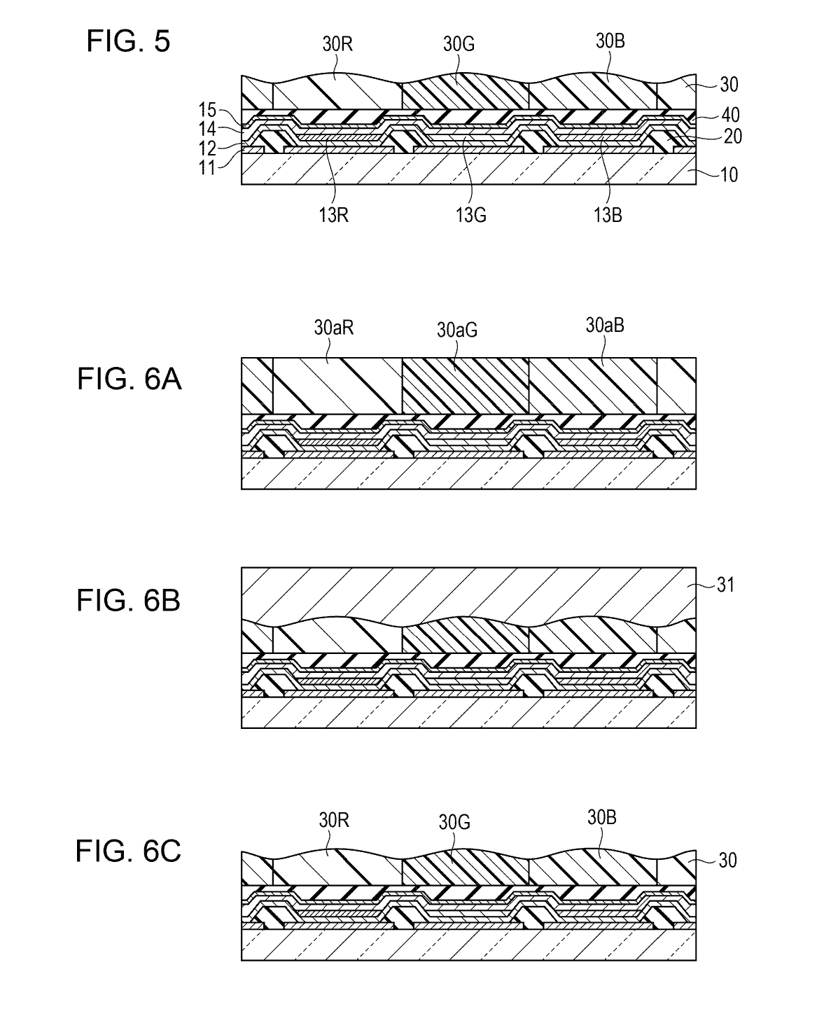

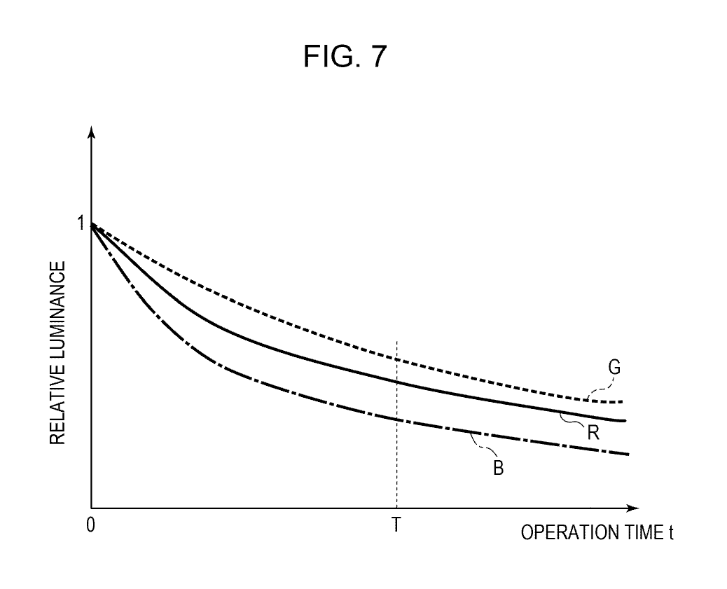

FIG. 5 is a schematic fragmentary sectional view of a display apparatus according to a second embodiment. In the display apparatus of the first embodiment, the organic EL elements are provided with lenses having different radiuses of curvature among colors so that the condensing characteristics of each lens can be controlled to reduce the difference among the deterioration properties of the organic EL elements. On the other hand, in the present embodiment, the organic EL elements are provided with lenses having different refractive indices among colors so that the condensing characteristics of each lens can be controlled to reduce the difference among the deterioration properties of the organic EL elements.

In general, the condensing characteristics of a convex lens increase as the refractive index of the lens is increased. Accordingly, a pixel having an organic EL element having a high deterioration rate (whose relative luminance is reduced at a high rate) is provided with a lens having a high refractive index so as to increase the condensing characteristics, and a pixel having an organic EL element having a low deterioration rate (whose relative luminance is reduced at a low rate) is provided with a lens having a low refractive index.

For example, consider the case where deterioration rate of the organic EL elements is increased in this order: the G element, the R element and the B element (deterioration rate of G element<deterioration rate of R element<deterioration rate of B element). In this instance, as shown in FIG. 5, the refractive indices of the convex lenses of the G element, the R element, and the B element increase in that order (refractive index of the lens of the G element<refractive index of the lens of the R element<refractive index of the lenses of the B element). In this structure, the pixel having the B element provided with a lens having a high refractive index and high condensing characteristics can exhibit an increased front luminance. Accordingly, the current density supplied to this pixel can be reduced to suppress the deterioration. Consequently, the deterioration rate of the B element is reduced. Even if it is driven for a long time, the decrease in relative luminance can be suppressed, and the deterioration property of the B element can be brought close to that of the G element. Similarly, the deterioration property of the pixel having the R element can be brought close to that of the G element. Since the deterioration properties of the B element and the R element thus become close to that of the G element, the chromaticity deviation of white, which is a mixed color of red, green and blue, can be prevented even after an operation for a desired period of time.

In a display apparatus that displays a desired white color by mixing a plurality of emission colors, it is preferable that the refractive index of the lens provided for each pixel be determined in view of the luminance ratio (color mixing ratio), luminous efficiency and luminance half-life of the colors required for displaying the white, as well as the deterioration property of each color element.

The display apparatus of the present embodiment can be manufactured by the same process as in the first embodiment. In the present embodiment, the radius of curvature of the convex lenses may be the same or difference among the pixels. In particular, the pixel including an organic EL element having a high deterioration rate can be provided with a lens having a small radius of curvature, and the pixel including an organic EL element having a low deterioration rate can be provided with a lens having a large radius of curvature, as in the first embodiment.

In order to control the refractive index, the refractive index of the resin forming the lens may be controlled. Also, an inorganic material may be added to the resin forming the lens to adjust the refractive index of the inorganic material or the resin content. For example, an inorganic material having a high refractive index may be used, such as titanium oxide (2.90), ITO (2.12), mercury sulfide (2.81), cobalt green (1.97), or cobalt blue (1.74).

### Other Embodiment

The condensing characteristics can be controlled by other methods different from the methods of the first and second embodiments. For example, the condensing characteristics may be controlled depending on the area of the pixel occupied by the lens. In this instance, the following approach is effective. The pixel including an organic EL element having a high deterioration rate can be provided with a lens in a larger area of the pixel, and the pixel including an organic EL element having a low deterioration rate can be provided with a lens in a smaller area of the pixel. Thus, the ratio of the light transmitted through the lens to the light emitted from the light-emitting region (pixel) can be controlled, so that the condensing characteristics of the pixels can be controlled.

In the above embodiments, lenses are provided so that the deterioration property is brought closer to that of color having a low deterioration rate. However, lenses may be provided so that the deterioration property can be brought closer to that of color having a high deterioration rate. This structure can also reduce white chromaticity deviation. More specifically, the following structure may be provided.

A structure having a convex lens and a structure having a concave lens may be combined to adjust the condensing characteristics. Structures having concave lenses have condensing characteristics lower than structures having convex lenses and still lower than structures not having a lens, thus exhibiting higher light-diffusing property. Accordingly, a pixel including an organic EL element having a low deterioration rate is provided with a concave lens, and another pixel including an organic EL element having a high deterioration rate may be provided with a convex lens.

Alternatively, the condensing characteristics (light-diffusing property) of the pixels may be controlled with only concave lenses, using the nature of concave lenses whose condensing characteristics decrease (light-diffusing property increases) as the radius of curvature is reduced. More specifically, a pixel including an organic EL element having a low deterioration rate can be provided with a concave lens having a small radius of curvature, and a pixel including an organic EL element having a high deterioration rate can be provided with a concave lens having a large radius of curvature. This structure can also reduce the difference in deterioration property among organic EL elements emitting different colors.

The display apparatus according to an embodiment of the invention may be used in a TV set, a personal computer, an image-pickup apparatus, a cellular phone display, or a portable game machine. Furthermore, the display apparatus can be used in a portable music player, a personal digital assistant (PDA), or a car navigation system.

### EXAMPLES

### Example 1

In Example 1, the difference among the deterioration properties of organic EL elements was reduced by using lenses having different radiuses of curvature. This will be described with reference to FIGS. 4A to 4E.

First, low-temperature polysilicon TFTs were formed on a glass substrate. Then, a silicon nitride insulating interlayer and an acrylic resin planarizing layer were formed on the substrate in that order, and thus, a substrate 10 shown in FIG. 4A was formed. An ITO/AlNd composite layer was formed to thicknesses of 38 nm/100 nm on the substrate 10 by sputtering. Subsequently, the ITO/AlNd composite layer was patterned into first electrodes 11.

The first electrodes 11 were coated with an acrylic resin by spin coating, and the acrylic resin coating was patterned into an insulating layer 20 so as to form openings corresponding to the positions of the first electrodes 11 by lithography (the regions where the opening were formed correspond to pixels). The pixels were disposed at a pitch of 30 μm, and the width of the first electrode 11 exposed in the opening was 10 μm. The resulting structure was subjected to ultrasonic cleaning with isopropyl alcohol (IPA) and boiling cleaning, followed by drying. After UV/ozone cleaning was further performed, organic compound layers were formed by vacuum vapor deposition as below. The organic compound layers were formed in a vacuum of 1×10⁻⁴ to 3.0×10⁻⁴ Pa at a deposition rate of 0.2 to 0.5 nm/s.

First, a hole transport layer 12 was formed of the compound having the following structure to a thickness of 87 nm commonly over the first electrodes 11.

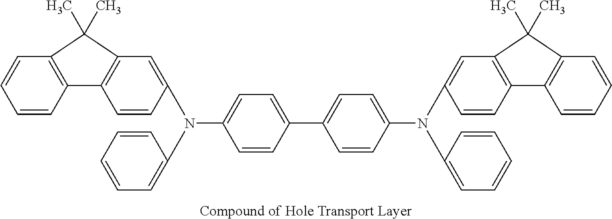

Then, 4,4′-N,N′-dicarbazole-biphenyl (CBP) and tris(1-phenylquinoline) iridium (Ir(piq)₃) in a weight ratio of 91:9 were co-deposited to a thickness of 30 nm on the portions that were to act as pixels emitting red light through a vapor deposition mask, thus forming red luminescent layers 13R. Then, tris-(8-hydroxyquinoline)aluminum (Alq₃) and coumarin 6 in a weight ratio of 99:1 were co-deposited to a thickness of 40 nm on the portions that were to act as pixels emitting green light through a vapor deposition mask, thus forming green luminescent layers 13G. Then, bis(2-methyl-8-quinolinolato)(p-phenylphenolato)aluminum (BAlq) and perylene in a weight ratio of 97:3 were co-deposited to a thickness of 25 nm on the portions that were to act as pixels emitting blue light through a vapor deposition mask, thus forming blue luminescent layers 13B.

Subsequently, bathophenanthroline (Bphen) was deposited to a thickness of 10 nm in the entire display region to form a common electron transport layer 14. Furthermore, a common electron injection layer (part of the electron transport layer 14) was formed to a thickness of 40 nm over the electron transport layer 14 by co-depositing Bphen and Cs₂CO₃ in a weight ratio of 90:10.

Subsequently, the resulting structure was transferred to a sputtering apparatus with a vacuum maintained, and Ag and ITO were deposited in that order to thicknesses of 10 nm and 50 nm, respectively, thus forming a second electrode 15.

Then, as shown in FIG. 4B, a silicon nitride protective layer 40 was formed by plasma CVD using SiH₄ gas, N₂ gas and H₂ gas.

As shown in FIG. 4C, a resin material layer 30a was formed by applying a thermosetting epoxy resin having a viscosity of 3000 mPa·s using a dispenser (SHOT MINI SL, manufactured by Musashi Engineering).

Before thermally curing the resin material layer 30a, a separately prepared die 31 for forming convex lenses 30R, 30G and 30B was pressed on the surface of the resin material layer 30a, as shown in FIG. 4D. For pressing the die 31, the die 31 and the substrate were positioned with each other so that the alignment mark of the die and the alignment mark of the substrate 10 were aligned. Thus, the convex lenses 30R, 30G and 30B were formed corresponding to the pixels. The die 31 had recesses at the same pitch as the pixels, and its surface was coated with a fluorocarbon resin coating as a release agent. The recesses had radiuses of curvature corresponding to the red, green and blue pixels, and they were 35 μm, 25.5 μm and 12 μm, respectively. The thickness of the lens member 30 was 20 μm.

Allowing for foreign matter that might occur depending on the environment of the clean room and the process system, the minimum thickness (thickness of the thinnest portions) of the lens member 30 was set to 10 μm so that the resin material layer 30a was able to absorb foreign matter or the like to make the surface smooth.

Subsequently, the resin material layer 30a was cured by heating at 100° C. for 15 minutes in vacuum with the die 31 pressed on the resin material layer 30a, thus forming the lens member 30. Then, the die 31 was removed from the lens member 30, and thus the convex lenses 30R, 30G and 30B were completed as shown in FIG. 4E. The radiuses of curvature of the convex lenses 30R, 30G and 30B were 35 μm, 25.5 μm and 12 μm, respectively.

Furthermore, a silicon nitride inorganic protective layer (not shown) was formed by plasma CVD using SiH₄ gas, N₂ gas and H₂ gas. This protective layer had a thickness of 1 μm and covered the entire display region.

The display apparatus thus prepared was evaluated for the characteristics, and the results are shown in Table 1. The independent element luminous efficiency and the independent element luminance half-life shown in the table are results of evaluation of the organic EL elements not provided with lenses. The pixel luminance half-life is the time taken until the luminance of each pixel decreases to a half the luminance of the pixel at the beginning of the operation when the pixel was driven at a current required for displaying white represented by CIExy chromaticity coordinates (0.310, 0.329). The relative luminances after 1000 hours and after 10000 hours are values relative to the luminance, defined as 1, at the beginning of the operation of each pixel. The δu′v′ after 10000 hours refers to the color difference between the white observed in the display apparatus after white was continuously displayed for 10000 hours and the white observed at the beginning of use.

TABLE 1

| | Red pixel | | Green pixel | | Blue pixel | |
|---|---|---|---|---|---|---|
| Chromaticity | (0.671, | 0.329) | (0.213, | 0.707) | (0.134, | 0.082) |
| Independent element luminous efficiency | 12.0 | cd/A | 10.0 | cd/A | 5.0 | cd/A |
| Independent element luminance half-life | 80,000 | hours | 90,000 | hours | 10,000 | hours |
| Luminance ratio in displaying white | 0.292 | | 0.601 | | 0.107 | |
| Magnification of front luminance | 1.59 | | 3.55 | | 11.16 | |
| (when lens is not provided: 1) | | | | | | |
| Luminous efficiency | 19.0 | cd/A | 35.5 | cd/A | 55.8 | cd/A |

| | | | |
|---|---|---|---|
| Rate of current required for displaying | 8.0 | 8.9 | 1.0 |
| white | | | |
| Pixel luminance half-life | 1.0 | 1.0 | 1.0 |
| Relative luminance after 1000 hours | 0.933 | 0.934 | 0.933 |
| Relative luminance after 10000 hours | 0.498 | 0.506 | 0.500 |

| | |
|---|---|
| δu′v′ after 10000 hours | 0.001 |

Table 1 shows that, in the display apparatus of Example 1, the condensing characteristics of the lenses were controlled to reduce the difference in deterioration property among emission colors. Consequently, the difference in luminance half-life among pixels was reduced, and the relative luminances after a 1000 hour operation and a 10000 hour operation did not differ much among emission colors. Furthermore, the δu′v′ after 10000 hours was 0.001. This means that the display apparatus of the present example had satisfactory characteristics, exhibiting a reduced white chromaticity deviation.

### Example 2

Example 2 was different from Example 1 in that the pixel including the organic EL element emitting red light was not provided with a lens, the pixel including the organic EL element emitting green light was provided with a convex lens having a radius of curvature of 31 μm, and the pixel including the organic EL element emitting blue light was provided with a convex lens having a radius of curvature of 18 μm.

The display apparatus thus prepared was evaluated for the characteristics, and the results are shown in Table 2. In the results shown in the table, the chromaticity of each independent element is different from the results of Example 1. This is probably because the thicknesses of the organic compound layers, the electrodes, or other layers have variations and differ from those in Example 1.

TABLE 2

| | Red pixel | | Green pixel | | Blue pixel | |
|---|---|---|---|---|---|---|
| Chromaticity | (0.675, | 0.325) | (0.205, | 0.685) | (0.139, | 0.068) |
| Independent element luminous efficiency | 10.8 | | 9.5 | | 4.2 | |
| Independent element luminance half-life | 80,000 | hours | 90,000 | hours | 10,000 | hours |
| Luminance ratio in displaying white | 0.284 | | 0.631 | | 0.085 | |
| Magnification of front luminance | 1 | | 2.24 | | 6.92 | |
| (when lens is not provided: 1) | | | | | | |
| Luminous efficiency | 10.8 | cd/A | 21.3 | cd/A | 29.1 | cd/A |

| | | | |
|---|---|---|---|
| Rate of current required for displaying | 13.8 | 15.5 | 1.5 |
| white | | | |
| Pixel luminance half-life | 0.6 | 0.6 | 0.7 |
| Relative luminance after 1000 hours | 0.888 | 0.887 | 0.900 |
| Relative luminance after 10000 hours | 0.304 | 0.303 | 0.349 |

| | |
|---|---|
| δu′v′ after 10000 hours | 0.01 |

The rate of current required for displaying white is a value relative to the current defined as 1 that the blue pixel of Example 1 required for displaying white. Table 2 shows that, in the display apparatus of Example 2, the condensing characteristics of the lenses were controlled to reduce the difference in deterioration property among emission colors. Consequently, the difference in luminance half-life among pixels was reduced, and the relative luminances after a 1000 hour operation and a 10000 hour operation did not differ much among emission colors. Furthermore, the δu′v′ after 10000 hours was 0.001. This means that the display apparatus of the present example had satisfactory characteristics, exhibiting a reduced white chromaticity deviation.

### Example 3

In Example 3, the difference among the deterioration properties of the organic EL elements was reduced by adjusting the refractive indices of convex lenses.

The display apparatus of Example 3 was prepared by the same process as in Example 1, except that the material of the lens member was applied in a different manner, and the surface of the lens die 31 had a different shape. After the silicon nitride protective layer 40 was formed as in Example 1, resin material members 30aR, 30aG and 30aB (FIG. 6A) were formed by applying an epoxy resin containing titanium oxide to the positions of the corresponding pixels, using a nozzle dispenser. In this instance, the nozzle at the position corresponding to the red pixel was filled with an epoxy resin, and the nozzles at the positions corresponding to the green pixel and the blue pixel were filled with the epoxy resin containing titanium oxide fine particles in different proportions. The amounts of titanium oxide in the epoxy resin filling the nozzles corresponding to the green and blue pixels were 22% by weight and 52% by weight, respectively, relative to the epoxy resin.

Then, as shown in FIG. 6B, a separately prepared die 31 was pressed on the resin material members 30aR, 30aG and 30aB, thus forming convex lenses. The die 31 used in Example 3 had recesses at the same pitch as the pixels, and the surfaces of the lenses 30R, 30G and 30B had the same shape.

Subsequently, the resin material members 30aR, 30aG and 30aB were cured by heating at 100° C. for 15 minutes in vacuum with the die 31 pressed on the resin material members 30aR, 30aG and 30aB, thus forming a lens member 30. Then, the die 31 was removed from the lens member 30, and thus the convex lenses 30R, 30G and 30B were completed as shown in FIG. 6C. The radiuses of curvature of the convex lenses 30R, 30G and 30B were the same 25 μm.

The convex lens 30R was formed of an epoxy resin having a refractive index of 1.54, and the convex lenses 30G and 30B were formed of a mixture containing this epoxy resin and titanium oxide fine particles having a refractive index of 2.9. By increasing the titanium oxide content in the mixture in the order of the R element, the G element and the B element, the refractive indices of the lenses were increased in the order of the R element, the G element and the B element (refractive index of R element lens<refractive index of G element lens<refractive index of B element lens).

The display apparatus thus prepared was evaluated for the characteristics, and the results are shown in Table 3.

TABLE 3

| | Red pixel | | Green pixel | | Blue pixel | |
|---|---|---|---|---|---|---|
| Chromaticity | (0.671, | 0.329) | (0.213, | 0.707) | (0.134, | 0.082) |
| Independent element luminous efficiency | 12.0 | cd/A | 10.0 | cd/A | 5.0 | cd/A |
| Independent element luminance half-life | 80,000 | hours | 90,000 | hours | 10,000 | hours |
| Luminance ratio in displaying white | 0.292 | | 0.601 | | 0.107 | |
| Magnification of front luminance | 1.59 | | 3.55 | | 11.16 | |
| (when lens is not provided: 1) | | | | | | |
| Luminous efficiency | 19.0 | cd/A | 35.5 | cd/A | 55.8 | cd/A |

| | | | |
|---|---|---|---|
| Rate of current required for displaying | 8.0 | 8.9 | 1.0 |
| white | | | |
| Pixel luminance half-life | 1.0 | 1.0 | 1.0 |
| Relative luminance after 1000 hours | 0.933 | 0.934 | 0.933 |
| Relative luminance after 10000 hours | 0.498 | 0.506 | 0.500 |

| | |
|---|---|
| δu′v′ after 10000 hours | 0.001 |

Table 3 shows that, in the display apparatus of Example 3, the condensing characteristics of the lenses were controlled to reduce the difference in deterioration property among emission colors. Consequently, the difference in luminance half-life among pixels was reduced, and the relative luminances after a 1000 hour operation and a 10000 hour operation did not differ much among emission colors. Furthermore, the δu′v′ after 10000 hours was 0.01. This means that the display apparatus of the present example had satisfactory characteristics, exhibiting a reduced white chromaticity deviation.

### Comparative Example

In the comparative example, the pixels were not provided with lenses, and the other parts were the same as in Example 1. In the results of the comparative example, the chromaticity of each independent element is different from the results of Example 1. This is probably because the thicknesses of the organic compound layers, the electrodes, or other layers have variations and differ from those in Example 1.

TABLE 4

| | Red pixel | | Green pixel | | Blue pixel | |
|---|---|---|---|---|---|---|
| Chromaticity | (0.675, | 0.325) | (0.188, | 0.693) | (0.142, | 0.061) |
| Independent element luminous efficiency | 10.8 | cd/A | 8.5 | cd/A | 3.8 | cd/A |
| Independent element luminance half-life | 80,000 | hours | 90,000 | hours | 10,000 | hours |
| Luminance ratio in displaying white | 0.291 | | 0.634 | | 0.075 | |
| Magnification of front luminance | 1 | | 1 | | 1 | |
| (when lens is not provided: 1) | | | | | | |
| Luminous efficiency | 10.8 | cd/A | 8.5 | cd/A | 3.8 | cd/A |

| | | | |
|---|---|---|---|
| Rate of current required for displaying | 14.1 | 39.0 | 10.3 |
| white | | | |
| Pixel luminance half-life | 0.6 | 0.2 | 0.1 |
| Relative luminance after 1000 hours | 0.885 | 0.740 | 0.491 |
| Relative luminance after 10000 hours | 0.295 | 0.049 | 0.001 |

| | |
|---|---|
| δu′v′ after 10000 hours | 0.041 |

Table 4 shows that the display apparatus of the comparative example exhibited a large difference in luminance half-life, and that the δu′v′ after a 10000 hour operation far exceeded the permissible value 0.020. The white displayed in this display apparatus after a 10000 hour operation was observed as orange.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-241206 filed Oct. 27, 2010 and No. 2011-187167 filed Aug. 30, 2011, which are hereby incorporated by reference herein in their entirety.

What is claimed is:

1. A display apparatus comprising:
a plurality of pixel units, each pixel unit including a plurality of pixels having different emission colors, each pixel including an organic EL element having a deterioration property, the pixel unit being provided with at least one lens so as to reduce a difference in deterioration property among emission colors of the pixels.

2. The display apparatus according to claim 1, wherein the at least one lens is provided such that the pixel deteriorating at a high rate has lens having higher condensing characteristics than the lens for the pixel deteriorating at a low rate.

3. The display apparatus according to claim 1, wherein the at least one lens is provided such that the pixel deteriorating at a high rate has a lens having condensing characteristics, whereas the pixel deteriorating at a low rate does not have a lens.

4. The display apparatus according to claim 2, wherein the at least one lens is a convex lens, and the condensing characteristics are controlled by a radius of curvature of the convex lens or a refractive index of the convex lens.

5. The display apparatus according to claim 4, wherein the pixel deteriorating at a high rate has a convex lens having a smaller radius of curvature than the convex lens for the pixel deteriorating at a low rate.

6. The display apparatus according to claim 4, wherein the pixel deteriorating at high rate has a convex lens having a higher refractive index than the lens for the pixel deteriorating at a low rate.

7. The display apparatus according to claim 2, wherein the pixel emits any one of red light, green light and blue light, and the organic EL element deteriorating at a high rate emits blue light.

8. The display apparatus according to claim 1, wherein the pixel emits any one of red light, green light and blue light, and the organic EL element deteriorating at a high rate emits blue light.

9. The display apparatus according to claim 3, wherein the pixel emits any one of red light, green light and blue light, and the organic EL element deteriorating at a high rate emits blue light.

10. The display apparatus according to claim 3, wherein the at least one lens is a convex lens, and the condensing characteristics are controlled by a radius of curvature of the convex lens or a refractive index of the convex lens.
